(19) United States
(12) Patent Application Publication
(10) Pub. No.: US 2009/0154605 A1
(43) Pub. Date: Jun. 18, 2009

(54) SYSTEM AND METHOD FOR PERFORMING DIRECT MAXIMUM LIKELIHOOD DETECTION

(75) Inventors: Jun Tan, Lake Zurich, IL (US); Amitava Ghosh, Buffalo Grove, IL (US); Fan Wang, Chicago, IL (US)

Correspondence Address: MOTOROLA, INC., 1303 EAST ALGONQUIN ROAD, IL01/3RD, SCHAUMBURG, IL, 60196, US

(73) Assignee: MOTOROLA, INC., Schaumburg, IL (US)

(21) Appl. No.: 11/954,998

(22) Filed: Dec. 12, 2007

(51) Int. Cl. H03D 1/00; H04L 27/06

(52) U.S. Cl. 375/341

(57) ABSTRACT

A method, wireless device, and wireless communication system perform Maximum Likelihood Detection. At least one data signal is accepting on at least one communication channel (604). The data signal is modulated with a plurality of transmitted bit values. The at least one data signal is sampled in a characteristic function domain of the data signal to produce characteristic function samples (608). A probability density function associated with the at least one data signal is determined, based upon the characteristic function samples (610). Soft decision values are determined, based upon the probability density function, for each transmitted bit value for each dimension of the at least one data signal (612).

### FIELD OF THE INVENTION

The present invention generally relates to the field of wireless communications, and more particularly relates maximum likelihood detection in the field of signal processing.

### BACKGROUND OF THE INVENTION

Wireless communication systems are currently utilizing devices that can include multiple receive and transmit antennas. One technology of utilizing multiple transmit and receiving antennas is usually referred to as Multiple-Input-Multiple-Output (“MIMO”) technology. In a MIMO system, a receiver and transmitter communicate over multiple antennas. In MIMO, multiple lower data rate streams are created from a single higher data rate signal. Different transmitting antennas in the same frequency channel each transmit a different one of these multiple low rate stream. This process can be referred to as spatial multiplexing. Ideally, the streams are received at a set of receiving antennas with different spatial signatures so that the streams can be separated. However, if the spatial signatures are too close to one another, the receiving antennas may have problems separating the streams or detection of the streams can become very complex.

To overcome the above problem, many receivers utilize Maximum Likelihood detection (“MLD”) for detecting spatially multiplexed signals. MLD allows for the detection of spatially multiplexed signals. A MLD receiver searches over a set of all possible transmit signals to find the best match with the actual received signal. A MLD receiver is an optimized receiver in the sense of maximum likelihood and therefore provides the best link performance. However, current MLD methods are problematic. For example, conventional MLD uses an exhaustive search where the search complexity increases exponentially with the number of detectable bits. For example, in a MIMO system with two transmit antennas, where each antenna uses 64 QAM and therefore each antenna has 64 possible constellation points to transmit, the total number of possible transmitted constellation points becomes 64²=4,096. In a similar system with four transmit antennas, the number of possible transmitted constellation points is 64⁴=16,777,216. As a result, conventional MLD is difficult to implement in hardware.

Therefore a need exists to overcome the problems with the prior art as discussed above.

### SUMMARY OF THE INVENTION

Briefly, in accordance with the present invention, disclosed are a method, wireless device, and wireless communication system for performing Maximum Likelihood Detection. In accordance with one embodiment, a method for performing Maximum Likelihood Detection includes accepting at least one data signal on at least one communication channel, wherein the data signal is modulated with a plurality of transmitted bit values. The method further includes sampling the at least one data signal in a characteristic function domain of the data signal to produce characteristic function samples. The method also includes determining, based upon the characteristic function samples, a probability density function associated with the at least one data signal. The method further includes determining, based upon the probability density function, soft decision values for each transmitted bit value for each dimension of the at least one data signal.

In another embodiment a wireless device is disclosed. The wireless device includes a memory and a processor that is communicatively coupled to the memory. The wireless device also includes a direct Maximum Likelihood Detection module that is communicatively coupled to the memory and the processor. The direct Maximum Likelihood Detection module includes a receiver adapted to accepting at least one data signal on at least one communication channel, wherein the data signal is modulated with a plurality of transmitted bit values. The direct Maximum Likelihood Detection module further includes a characteristic domain sampler that is adapted to sampling the at least one data signal in a characteristic function domain of the data signal to produce characteristic function samples. The direct Maximum Likelihood Detection module also includes a probability density function determiner that is adapted to determining, based upon the characteristic function samples, a probability density function associated with the at least one data signal. The direct Maximum Likelihood Detection module also includes a soft decision value determiner that is adapted to determining, based upon the probability density function, soft decision values for each transmitted bit value for each dimension of the at least one data signal.

In yet another embodiment, a wireless communication system for performing Maximum Likelihood Detection is disclosed. The wireless communication system includes a plurality of base stations and a plurality of wireless devices. Each wireless device in the plurality of wireless devices is communicatively coupled to at least one base station in the plurality of base stations. At least one of a wireless device and a base station include a direct Maximum Likelihood Detection module that is communicatively coupled to the memory and the processor. The direct Maximum Likelihood Detection module includes a receiver adapted to accepting at least one data signal on at least one communication channel, wherein the data signal is modulated with a plurality of transmitted bit values. The direct Maximum Likelihood Detection module further includes a characteristic domain sampler that is adapted to sampling the at least one data signal in a characteristic function domain of the data signal to produce characteristic function samples. The direct Maximum Likelihood Detection module also includes a probability density function determiner that is adapted to determining, based upon the characteristic function samples, a probability density function associated with the at least one data signal. The direct Maximum Likelihood Detection module also includes a soft decision value determiner that is adapted to determining, based upon the probability density function, soft decision values for each transmitted bit value for each dimension of the at least one data signal.

An advantage of the foregoing embodiments of the present invention is that it provides a direct MLD method that reduces the processing complexity of conventional MLD implementations. The present invention allows for the direct calculation of MLD soft decision values based on characteristic domain samples. Another advantage is that one dimensional sampling and bitwise combination is provided to yield the MLD values. Multi-dimensional sampling in the characteristic domain is performed in one embodiment to provide improved MLD values. Yet another advantage is that the direct MLD process determines a sampling period and a number of samples to balance the tradeoff of performance and complexity.

### BRIEF DESCRIPTION OF THE DRAWINGS

The accompanying figures where like reference numerals refer to identical or functionally similar elements throughout the separate views, and which together with the detailed description below are incorporated in and form part of the specification, serve to further illustrate various embodiments and to explain various principles and advantages all in accordance with the present invention.

FIG. 1 is block diagram illustrating a wireless communication system, according to an embodiment of the present invention;

FIG. 2 is schematic of a transmitter-receiver structure according to an embodiment of the present invention;

FIG. 3 is an illustrative example for performing Direct Maximum Likelihood Detection according to an embodiment of the present invention;

FIG. 4 is a block diagram illustrating a detailed view wireless device according to an embodiment of the present invention;

FIG. 5 is an operational flow diagram illustrating a process of performing Direct Maximum Likelihood Detection according to an embodiment of the present invention.

### DETAILED DESCRIPTION

As required, detailed embodiments of the present invention are disclosed herein; however, it is to be understood that the disclosed embodiments are merely examples of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting; but rather, to provide an understandable description of the invention.

The terms “a” or “an”, as used herein, are defined as one or more than one. The term plurality, as used herein, is defined as two or more than two. The term another, as used herein, is defined as at least a second or more. The terms including and/or having, as used herein, are defined as comprising (i.e., open language). The term coupled, as used herein, is defined as connected, although not necessarily directly, and not necessarily mechanically.

The term wireless device is intended to broadly cover many different types of devices that can wirelessly receive signals, and optionally can wirelessly transmit signals, and may also operate in a wireless communication system. For example, and not for any limitation, a wireless device can include any one or a combination of the following: a cellular telephone, a mobile phone, a smartphone, a two-way radio, a two-way pager, a wireless messaging device, a laptop/computer, automotive gateway, residential gateway, and the like. A wireless device can also include wireless communication cards that are communicatively coupled to an information processing system. The information processing system can include a personal computer, a personal, digital assistant, a smart phone, and the like.

Wireless Communication System

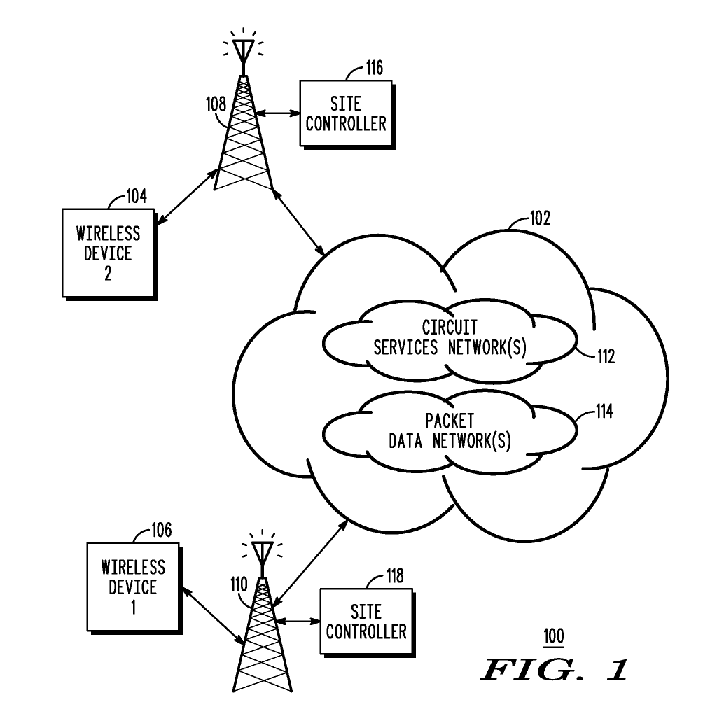

According to an embodiment of the present invention as shown in FIG. 1 a wireless communication system 100 is illustrated. FIG. 1 shows a wireless communication network 102 communicatively coupled to one or more wireless devices 104, 106. The wireless devices 104, 106 in one embodiment, are also communicatively coupled to one or more base stations 108, 110. The wireless communication network 102 can comprise one or more circuit service networks 112 and/or packet data networks 114.

The wireless communication system 100 supports any number of wireless devices 104, 106 which can be single mode or multi-mode devices. Multi-mode devices are capable of communicating over multiple access networks with varying technologies. For example, a multi-mode device can communicate over various access networks using various services such as Push-To-Talk (“PTT”), Push-To-Talk Over Cellular (“PoC”), multimedia messaging, web browsing, VoIP, multimedia streaming, and the like.

Each base station 108, 110 can be communicatively coupled to a site controller 116, 118. In one embodiment, the wireless communication network 102 is capable of broadband wireless communications utilizing time division duplexing (“TDD”) as set forth, for example, by the IEEE 802.16e standard. It should be noted that applications of the present invention are not limited to 802.16e systems implementing TDD. MLD processing used in other areas, for example in other communication systems that are able to incorporate MLD processing provided by further embodiments of the present invention include UMTS LTE, 802.20 systems, and the like. Further applications for the MLD processing described herein include use in systems where TDD may be only used for a portion of the available communication channels in the system 100, while one or more schemes are used for the remaining communication channels. The MLD processing implemented by embodiments of the present invention are able to be used in any suitable application.

Direct MLD

The wireless devices 104, 106 of one embodiment of the present invention communicate with base stations 108, 110 by using OFDM/OFDMA/DFT-SOFDM modulation. The receivers of one embodiment utilize a maximum likelihood of Detection (MLD) processing technique to detect received data. As discussed above, conventional MLD is computationally expensive because it performs an exhaustive search. The number of operations exponentially increases as the number of transmit antennas increase. This makes implementing conventional MLD in, for example, MIMO receivers very difficult. One embodiment of the present invention, on the other hand uses a reduced complexity MLD method that is referred herein as direct MLD. This direct MLD reduces processing complexity by directly computing soft data decisions by using a Log Likelihood Ratio (“LLR”) as is described below. One embodiment of the present invention uses samples in the characteristic function domain of received baseband signals to yield a probability calculation for soft data decisions. This embodiment of the present invention then performs the equivalent of convolutions by multiplying characteristic function samples in characteristic domain to reduce the processing complexity required to perform MLD data detection.

The direct MLD calculation performed by one embodiment of the present invention has reduced computational complexity as compared to conventional algorithms for performing MLD. For example, consider an nₜ×nᵣ MIMO with 2^{k}-ary modulation, where nₜ is the number of transmit antennas, nᵣ is the number of receive antennas. Defining O(x) to represent the order of complexity of a function as varying with “x” and defining L as the number of samples, the complexity of conventional MLD calculations, which performs an exhaustive search over all possible channel symbol combinations, is o(2^{kn}^{ₜ}), i.e., its complexity increases exponentially. However, the complexity of the direct MLD utilized by one embodiment of the present invention is O(4nᵣL), i.e., its complexity increases linearly when 1-D sampling is performed for each of 4nᵣ dimensions and bit-by-bit combination for all dimensions is used. It should be noted that the embodiment of the present invention being discussed implements MLD in a MIMO receiver. However, further embodiments of the present invention are not limited to MIMO receivers and can be applied to any application where MLD is performed, such as applications including maximum likelihood sequence detection, multi-user detection, interference cancellation, DFT-S OFDM, and the like.

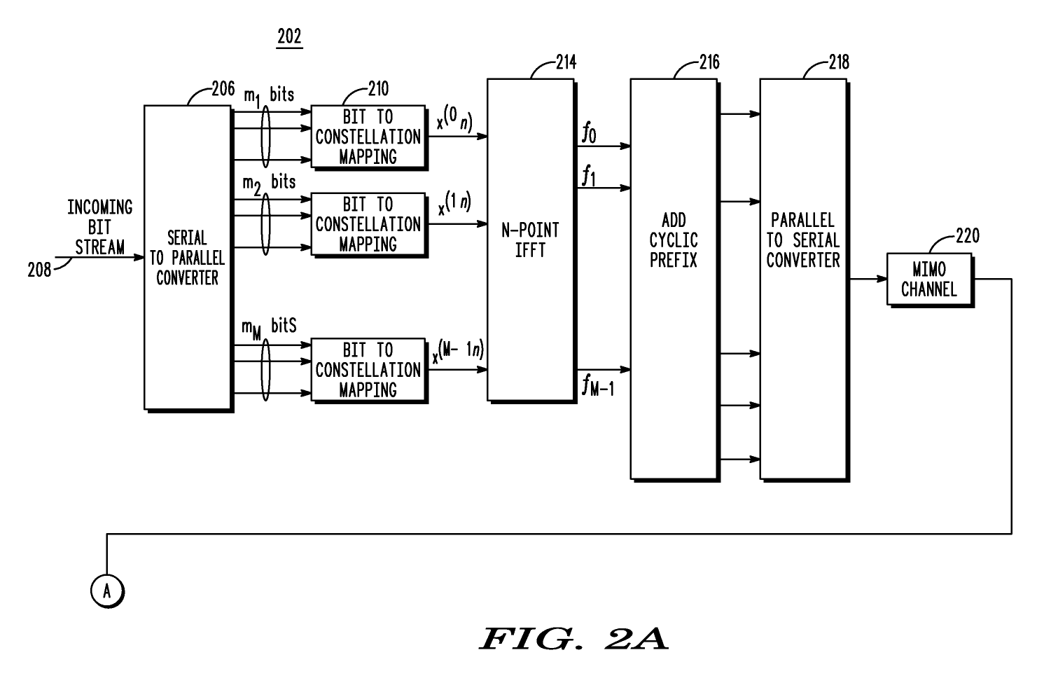

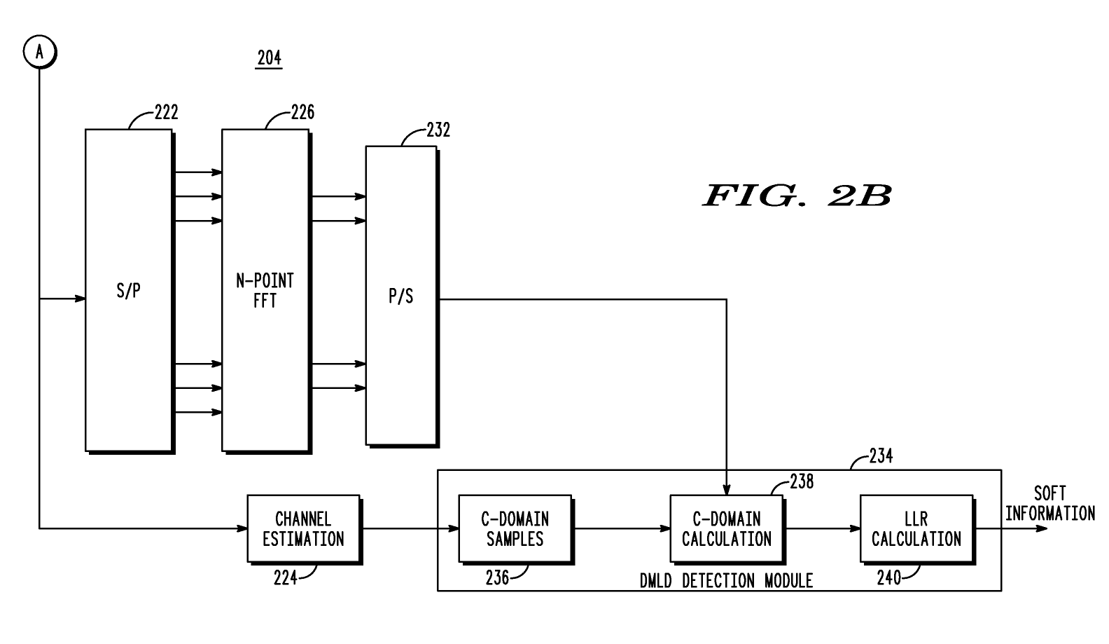

FIG. 2 shows a schematic of a transmitter-receiver structure according to an embodiment of the present invention. The receiver can be located at a wireless device 104, 106, a base station 108, 110, or any other device/component comprising multiple receive antennas. FIG. 2 shows a transmitter that transmits multiple signals from multiple antennas to a receiver 204 that receives those signals through multiple receive antennas to implement MIMO data transmission. The transmitter 202 comprises a serial-to-parallel converter 206 that receives an incoming bit stream 208. The serial-to-parallel converter 206 outputs a plurality of bit sets to separate bit to constellation mapping modules 210. The bit to constellation mapping modules 210 accept a number of bits, e.g., m₁ bits, as required to define each channel symbol used for the particular communications system. For example, systems that communicate by transmitting BPSK incorporate bit to constellation mapping modules that each accept one bit, and systems that communicate by transmitting 64-QAM channel symbols incorporate bit to constellation mapping modules that each accept six bits.

The bit to constellation mapping modules 210 are electrically coupled to an N-point Inverse Fast Fourier Transform (“IFFT”) module 214. The “N” data point outputs of the N-point FFT 214 are electrically coupled to the cyclic prefix module 216. The cyclic prefix module 216 adds a cyclic prefix to the block at the output of N-point inverse FFT 214. A parallel-to-serial converter 218 accepts the output of the add cyclic prefix module 216 and provides that data stream to a MIMO channel 220.

The MIMO channel 220 of one embodiment incorporates MIMO RF transmission and RF reception hardware, as is commonly known to practitioners of ordinary skill in the art. A detailed explanation of the MIMO channel 220 is not provided here to simplify the understanding of the aspects of one embodiment of the present invention. The MIMO channel 220 of one embodiment provides quantized baseband, or other suitable intermediate frequency, signal samples that are processed by subsequent stages of the receiver 204.

The quantized received signal samples are passed on to a serial-to-parallel converter 222 and also to a channel estimation module 224. An N-point FFT 226 receives the output from the serial-to-parallel converter 222 and produces a frequency domain representation of the received signals. The N-point FFT 226 is electrically coupled to the parallel-to-serial module 232. The parallel-to-serial converter 232 receives the output of the N-point FFT 226 and produces a serialized baseband signal sample output.

The parallel-to-serial converter 232 of one embodiment outputs data to a direct MLD module 234. The channel estimation module 224 also outputs the channel characteristic estimation to the direct MLD module 234.

The direct MLD module 234 comprises a characteristic domain (which is also referred to as the “c-domain”) sampler 236, a c-domain calculation module 238, and a LLR module 240. The c-domain sampler 236 receives estimated channel gains from the channel estimation module 224. The c-domain sampler 236 determines c-domain sampling parameters, such as sampling approaches and sampling period in the c-domain. The c-domain calculation module 238 uses the sampling parameters and received frequency domain data from the parallel-to-serial converter 232 as inputs. An example of determining and calculating c-domain samples and corresponding probability density functions is described below with regards to FIG. 6.

The LLR module 240 calculates soft decision values that are provided to, for example, a conventional channel decoder within the receiver 204. The soft decision values produced by the LLR calculation 240 are able to be processed by any suitable processor that accepts soft decision data values. In other words, the direct MLD module 234 directly calculates the LLR soft decision values in a manner that reduces the complexity of the MLD process of one embodiment of the present invention. One embodiment of the present invention determines a set of refined soft decision values combining the soft decision values that have been determined over each dimension associated with the received signal for each corresponding bit in the plurality of transmitted bit values of each dimension

The direct MLD process is now discussed in greater detail using a MIMO system as an example. In the context of a MIMO system, the received signal in one time instance can be represented as:

$$( \begin{matrix}{y}_{0} \\ ⋮ \\ {y}_{{n}_{r} - 1}\end{matrix} ) = ( \begin{matrix}{a}_{00} & ⋯ & {a}_{{n}_{t} - 1 , 0} \\ ⋮ & ⋰ & ⋮ \\ {a}_{0 , {n}_{r} - 1} & ⋯ & {a}_{{n}_{t} - 1 , {n}_{r} - 1}\end{matrix} ) ( \begin{matrix}{x}_{0} \\ ⋮ \\ {x}_{{n}_{t} - 1}\end{matrix} ) + ( \begin{matrix}{z}_{0} \\ ⋮ \\ {z}_{{n}_{r} - 1}\end{matrix} )$$

The vector (y₀, . . . , yₙᵣ₋₁) is the received signal of nᵣ number of receive antennas. The vector (x₀, . . . , xₙₜ₋₁) is the transmit vectors of nₜ number of transmit antennas. The matrix {a_{i,j}} is the channel gain of the MIMO channel. The vector (z₀, . . . , zₙᵣ₋₁) is the Gaussian noise vector for nᵣ number of receiving antennas. The transmit symbols (x₀, . . . , xₙₜ₋₁) have an alphabetical set as X=(c₀, . . . , c_{K-1}). The MLD process finds the symbol “x” using the equation:

$${x}^{⋒} = {arg min}_{x ∈ {X}^{{n}_{t}}} {‖ y - Ax ‖}^{2}$$

A soft decision using MLD, i.e. a Log-Likelihood Ratio (LLR), can also be calculated by the equation in the case of transmit BPSK channel symbols:

$$L ( {{x}^{⋒}}_{n} ) = log \frac{p ( y \vert {x}_{n} = + 1 )}{p ( y \vert {x}_{n} = - 1 )} \qquad ( EQ 2 )$$

It should be noted that BPSK is only used in this description as a non-limiting example.

In order to calculate the LLR for MLD, the probability density p(y) given a particular transmit bit should be known. Based on the MIMO channel equation, the received signal can be represented as

$$y = {\sum }_{j = 0}^{{n}_{t} - 1} {a}_{j} {x}_{j} + z \qquad ( EQ 3 )$$

where y is the received signal vector, z is the noise vector, and aⱼ is the column vector in the matrix A. Assuming that the probability of xⱼ=cᵢ is p_{j,l}, the probability density function (“PDF”) of aⱼxⱼ is”

Assuming all {xₙ}

$$p ( {a}_{j} {x}_{j} ) = {\sum }_{i = 0}^{κ - 1} {p}_{j , i} δ ( {a}_{j} {x}_{j} - {a}_{j} {c}_{i} ) \qquad ( EQ 4 )$$

Gaussian, the PDF of the received y becomes:

$$p ( y ) = {{*}^{{n}_{t} - 1}}_{j = 0} [ {\sum }_{i = 0}^{κ - 1} {p}_{j , i} δ ( y - {a}_{j} {c}_{i} ) ] * {( \frac{1}{\sqrt{2 π} σ} )}^{{n}_{r}} {e}^{\frac{1}{2 {σ}^{2}} {‖ y ‖}^{2}} \qquad ( EQ 5 )$$

where * represents convolution. The calculation of p(y) according to the above equation involves nₜ iterations of convolutions that have K terms each. The total number of resulting terms in p(y) is K^{nt}. Alternatively, the probability density function can be calculated through its characteristic function domain.

Given a multi-dimensional random variable y with probability density function p(y), the characteristic function of random variable y is defined by

Φ(λ)=E[e^{-j2π<λ,y>}]=∫p(y)e^{-j2π<λ,y>}dy, (EQ 6)

where λ is a multi-dimensional variable in the transformed domain, called the characteristic domain, or c-domain. The characteristic function of y is the Fourier transform of PDF p(y). Note the term <λ,y> is the inner product of two vectors, which is defined as:

$$< λ , y >= {\sum }_{i = 0}^{{n}_{r} - 1} {λ}_{i} {y}_{i} \qquad ( EQ 7 )$$

By taking the Fourier transform of p(y), the characteristic function of y can be represented as:

$$Φ ( λ ) = {\prod }_{j = 0}^{{n}_{t} - 1} [ {\sum }_{i = 0}^{κ - 1} {p}_{j , i} {e}^{- j 2 π < λ , {a}_{j} >} ] {e}^{- \frac{1}{2} {( 2 πσ )}^{2} {‖ λ ‖}^{2}} \qquad ( EQ 8 )$$

In one embodiment, the characteristic function of p(y) is easier to calculate than p(y) itself. Calculation of the characteristic function involves nₜ multiplications of K items. Therefore, the convolution operation is converted to multiplication. Since the c-domain variable λ is a multi-dimension continuous variable, samples in c-domain are used to represent Φ(λ) . Denote Φₖ as one dimension samples for a 1-dimensional c-domain. The PDF of y can be calculated with the c-domain samples as:

$$p ( y ) = \sqrt{2 π} {λ}_{0} {\sum }_{k} {Φ}_{k} {e}^{j2π k {λ}_{0} y} \qquad ( EQ 9 )$$

If the c-domain values are known, the PDF can be calculated through a Fourier transform. With the PDF of y, the soft decision values of each corresponding bit can be calculated by substituting p(y) of EQ 9 into EQ 2 above.

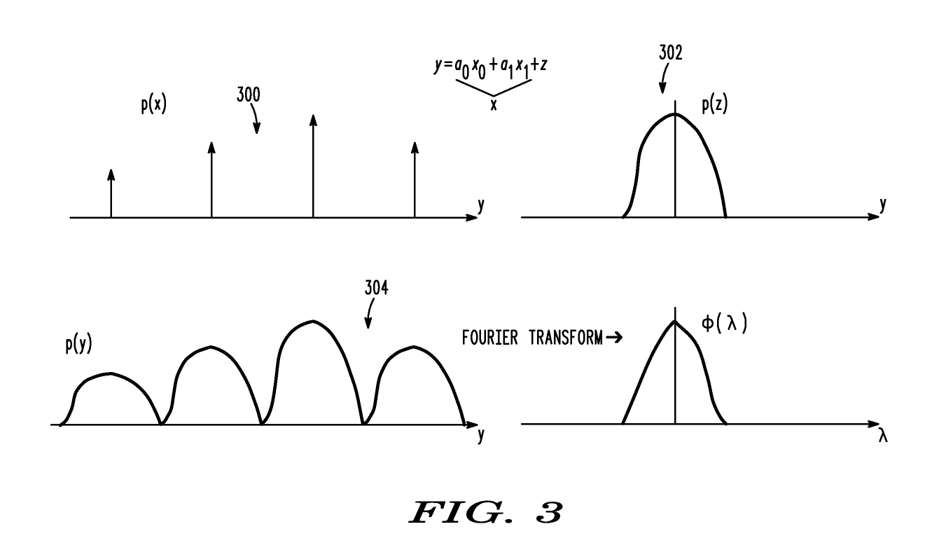

FIG. 3 shows an illustrative example of the above process for a transmitter with two transmitting antennas and a receiver with one receive antenna. A first transmit antenna is transmitting symbol x₀ and the second antenna is transmitting symbol x₁. The received signal is y and can be defined as:

y=a₀x₀+a₁x₁+z (EQ 10)

where z is noise and a₀ is channel gain between the first transmit antenna and the receiver and a₁ is the channel gain between the second transmit antenna and the receiver.

If x is adjusted to equal a₀x₀+a₁x₁ the probability density function of x is illustrated by the first graph 300. For a BPSK example, the p(x) is a series of delta functions of the four possible positions of the x. The four possible symbols that are able to be represented by the two BPSK data bits transmitted by the transmitter from the two transmit antennas are represented as S₀, S₁, S₂, and S₃. The p(z) (second graph 302) is the probability density function of the received noise, which is a Gaussian function.

Convolving p(x) and p(z) yields the probability density function p(y) of the received signal y, i.e., the received signal as is illustrated by the third graph 304. This is a multiple Gaussian function. Taking the Fourier transform of p(y) yields the characteristic function Φ(λ) of the random variable y. If the characteristic function Φ(λ) is known, the probability density function p(y) can be computed for any given received y.

The characteristic function is evaluated with samples in the characteristic function domain (c-domain). Sampling in the c-domain is accomplished as follows. A limited number of samples, denoted as Φ_{K} are used to accurately represent the characteristic function. For 1-D y, the PDF of the y can be defined as EQ 9 above, where λ₀ is the sampling period in the c-domain. Due to the Gaussian function, the c-function descends very fast. The dominating samples are those samples with small value of k. The Φ_{K} is used to calculate the p(y), which in turn is used by the direct MLD module 234 to calculate the LLR soft decision values.

One-dimensional sampling and bitwise combining can be characterized as follows. A received signal has a 2nᵣ dimension. The 2nᵣ dimension can be treated as 2nᵣ independent parallel channels. Therefore a 1-D sampling algorithm, in one embodiment, applies direct MLD for each dimension of received signal using 1-D samples and calculates soft decision values for all embedded bits in each dimension. The direct MLD module 234 then combines the soft decision values over dimensions for each corresponding embedded bit (bitwise combining). The complexity of this process can be characterized as O(2nᵣL), which is a linear complexity as compared to the complexity of conventional MLD O(2^{kn}^{ₜ}), which is exponential.

An advantage of one embodiment of the present invention is that even though complexity is proportional to the number of receive antennas, incorporating 1-D sampling and bitwise combining reduces this complexity. Another advantage of one embodiment of the present invention is that to achieve more optimal samples, the direct MLD module 234 performs multi-dimensional sampling.

With multi-dimensional sampling the dimension of received signal is 2nᵣ, due to using complex number representations and the samples can be defined as

$${Φ}_{{k}_{0} , {k}_{1} , … , {k}_{2 {n}_{r} - 1}} .$$

If L is the number of samples per dimension the total sample number is L²ⁿ^{ᵣ}. The complexity of the multidimensional process is exponential to the number of receive antennas, as compared to the exponential complexity to the number of transmit antennas of conventional MLD.

An alternative approach for multi-dimensional sampling of the received signal is referred to as random sampling, or Monte Carlo sampling. Random sampling takes a series of samples

$${Φ}_{{k}_{0} , {k}_{1} , … , {k}_{2 {n}_{r} - 1}}$$

in the c-domain, where indices k₀,k₁, . . . k₂ₙ_{ᵣ}₋₁ are random numbers, in the random sampling case, or pseudo-random numbers, in the pseudo-random sampling case, in their corresponding dimensions. All of the samples in the c-domain are then used to calculate the probability density function p(y) described above.

To summarize the above, the direct MLD performed by the direct MLD module 234 can be summarized as follows. A sampling period is determined based on signal weights (channel gains) and noise variance. Samples are taken in the characteristic domain corresponding to each input modulating symbol. The final c-domain values are calculated for each modulating bit. A one-point Fourier transform (the weighted sum) is taken to yield the probability for each modulating bit corresponding to bit-“1” or bit-“0”. With the probabilities of being 0 and being 1, the soft LLR value for each bit can then be calculated according to EQ 2 described above.

Exemplary Wireless Device

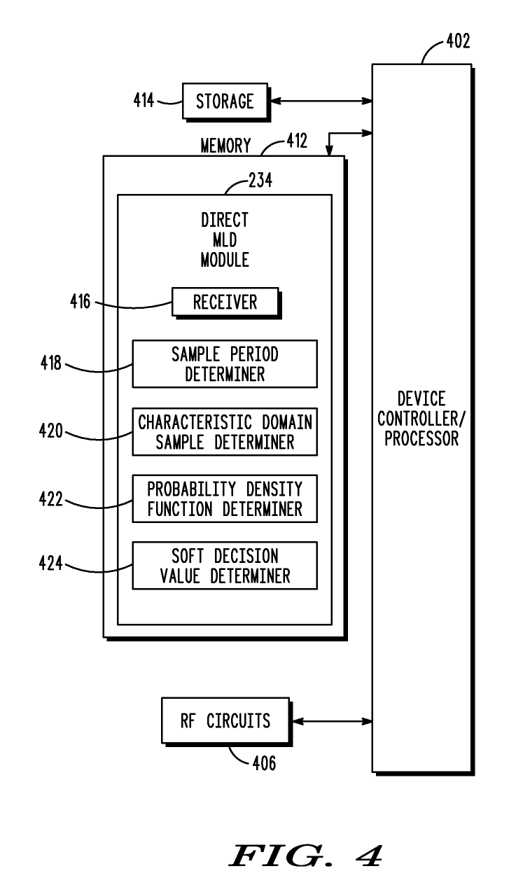

FIG. 4 is a block diagram illustrating a detailed view of the wireless device 106 according to an embodiment of the present invention. To simplify the present description, only that portion of a wireless communication device that implements the above described processing is discussed. The wireless device 106 operates under the control of a device controller/processor 402, that controls the sending and receiving of wireless communication signals. The device controller/processor 402 controls RF circuits 406 to implement bi-directional wireless communications. The device controller/processor 402 also performs digital signal processing to process received RF signals produced by the RF circuits 406 and to prepare signals for transmission by the RF circuits 406.

The device controller 402 operates the RF circuits 406 and performs digital signal processing according to instructions stored in the memory 412. The memory 412, in one embodiment, includes the direct MLD module 234, which is alternatively able to be implemented in hardware circuits in further embodiments of the present invention. The wireless device 106, also includes non-volatile storage memory 414 for storing, for example, further digital signal processing algorithms or other control programs (not shown) on the wireless device 106.

In one embodiment, the direct MLD module 234 includes a receiver 416 that is adapted to receive at least one digitized data signal derived from a received signal on at least one wireless communication channel. The data signal comprises at least one dimension that each include a plurality of transmitted bit values. The direct MLD module 234 also includes a sample period determiner 418 that is adapted to determine a sampling period in a characteristic function domain of at least one transfer function. Each of the at least one transfer function corresponding to a respective wireless communications channel within the at least one wireless communications channel. A characteristic domain sample determiner 420 is also included in the direct MLD module 234. The characteristic domain sample determiner 420 is adapted to determine characteristic domain samples in the characteristic function domain of each of the at least one transfer function according to the determined sampling period in the characteristic function domain.

The direct MLD module 234 also includes a probability density function determiner 422 that is adapted to determine a probability density function associated with the received signal using the determined samples. A soft decision value determiner 424 is also included in the direct MLD module 234. The soft decision value determiner 424 is adapted to determine soft decision values, in response to the probability density function, for each bit in the plurality of transmitted bit values for each dimension of the at least one data signal which has been received based on the characteristic domain samples. One or more of these components 416, 418, 420, 422, 424 can reside outside of the direct MLD module 234. Also, one or more of these components 416, 418, 420, 422, 424 can be implemented as software or hardware.

Process Of direct MLD

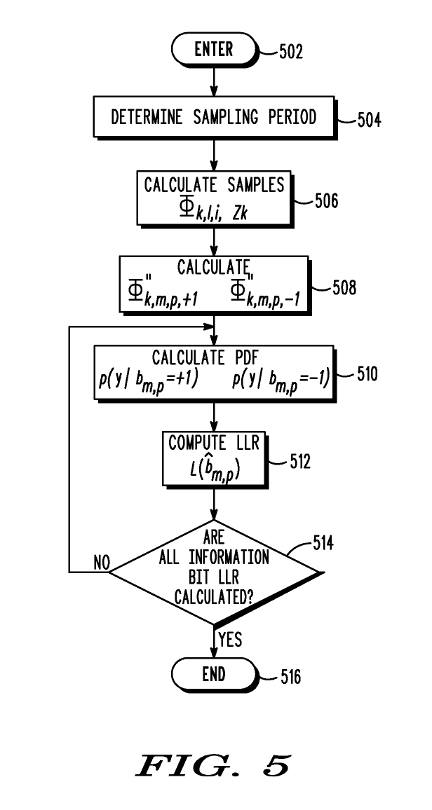

FIG. 5 is an operational flow diagram illustrating a process of direct MLD performed by a receiver. The example of FIG. 5 assumes the above described one-dimension example for the calculation of the LLR for the direct MLD process. The direct MLD 234 receives the following data sets for the processing illustrated in FIG. 5: the channel transfer function gains “A” from channel estimation process 224, channel SNR, a priori information p_{j,i} describing the probability of the occurrence of each channel symbol for each transmitted bit, and the received signal y.

The operational flow diagram of FIG. 5 begins at step 502 and flows directly to step 504. The direct MLD 234, at step 504, receives a data signal and determines a sampling number and sampling period for the received signals in the c-domain based. In one embodiment, the sampling number and sampling period is based on measured channel SNR. For a 1-D c-domain, the c-domain samples are denoted as λₖ.

The first step of the algorithm determines a number of samples and a sampling period in the c-domain for c-domain sampling. The c-domain sampling represents discrete c-domain samples of the continuous characteristic function Φ(λ) of at least one determined wireless communications channel transfer function. In general, the characteristic function is multi-dimensional to reflect the multiple transfer functions exhibited by a MIMO wireless channel.

The approach of one embodiment of the present invention uses a sequence of discrete samples

$$( {λ}_{{k}_{0}} , {λ}_{{k}_{1}} , … , {λ}_{{k}_{{n}_{r} - 1}} )$$

defined as:

$$( {λ}_{{k}_{0}} , {λ}_{{k}_{1}} , … , {λ}_{{k}_{{n}_{r} - 1}} ) = ( {k}_{0} {Δλ}_{0} , {k}_{1} {Δλ}_{1} , … , {k}_{{n}_{r} - 1} {Δλ}_{{n}_{r} - 1} )$$

In the above sequence, Δλᵢ is the c-domain sampling period in the i-th dimension, and kᵢ is an index in the i-th domain. One embodiment of the present invention uses a constant sampling period for all dimensions, that is, Δλᵢ=Δλ for all i. Further embodiments, however, are able to use different sampling periods in different dimensions.

Selecting a sampling period in the c-domain generally involves a tradeoff between processing complexity and performance. Smaller sampling periods provide better probability density calculation accuracy; but the number of samples is greater for a smaller sampling period. Since the c-function Φ(λ) is generally dominated by the Gaussian function, one embodiment uses the variance of the c-domain Gaussian function to determine the sampling period.

In an example representing the number of samples per dimension as N (with an assumption that the number of samples is the same for all dimensions), the sampling period per dimension is Δλ. Note that Φ(λ) is dominated by the Gaussian function:

$${e}^{- \frac{1}{2} {( 2 π σ )}^{2} {‖ λ ‖}^{2}} = {\prod }_{i} {e}^{- \frac{1}{2} {( 2 πσ )}^{2} {λ}_{i}^{2}} .$$

In the i-th dimension, the processing of one embodiment of the present invention selects a value of N and Δλ such that:

$$Δλ \leq \frac{1}{2 {max}_{i , x} \{ {\sum }_{j} \vert {a}_{i , j} \vert \vert {x}_{i} \vert \} ,}$$

$$N Δλ \geq \frac{{M}_{c}}{\sqrt{2 π} σ}$$

In one embodiment of the present invention, M_{c} is selected to equal six in order to include the dominant components of the Gaussian function. Based upon the above selected values of the sampling period Δλ and the sample number N, the sequence of samples

$$( {λ}_{{k}_{0}} , {λ}_{{k}_{1}} , … , {λ}_{{k}_{{n}_{r} - 1}} ) ,$$

described above, can be determined. For 1-D samples, this simply becomes λₖ.

The direct MLD 234, at step 506, calculates samples for each of nₜK terms, based on channel gain and a priori information p_{l,i}, as:

Φ_{k,l,i}=p_{l,i}e^{-j2πλ}^{ₖ}^{a}^{ⱼ} (EQ 11)

where i=0, . . . , K−1, l=0, . . . , nₜ−1.

The direct MLD 234 also calculates noise samples in c-domain as:

$${Z}_{k} = {e}^{- \frac{1}{2} {( 2 πσ )}^{2 {‖ {λ}_{k} ‖}^{2}}} \qquad ( EQ 12 )$$

For the m-th transmit antenna, the direct MLD 234, at step 508 calculates

$${Φ}_{k , m}^{′} = ( {\prod }_{l = 0 , l \neq m}^{{n}_{t} - 1} {\sum }_{i = 0}^{K - 1} {Φ}_{k , l , i} ) {Z}_{k} \qquad ( EQ 13 )$$

For each transmit bit b_{m,p} at the m-th antenna. The alphabetical set X is denoted into two sets, as

X_{p,+1}={cₙ|bₚ=+1, cₙ εX}

X_{p,-1}={cₙ|bₚ=−1, cₙ εX} (EQ 14)

Based upon the above equations, the processing calculates:

$${Φ}_{k , m , p , + 1}^{″} = {Φ}_{k , m}^{′} {\sum }_{i , {c}_{i} ∈ {X}_{p , + 1}}^{ } {Φ}_{k , m , i} \\ {Φ}_{k , m , p , - 1}^{″} = {Φ}_{k , m}^{′} {\sum }_{i , {c}_{i} ∈ {X}_{p , - 1}} {Φ}_{k , m , i} \qquad ( EQ 15 )$$

The direct MLD 234, at step 510, calculates the probability density function of y based on c-domain samples and received symbol y, as:

$$p ( y \vert {b}_{m , p} = + 1 ) = {\sum }_{k} {Φ}_{k , m , p , + 1}^{″} {e}^{j2π k {λ}_{0} y} \\ p ( y \vert {b}_{m , p} = - 1 ) = {\sum }_{k} {Φ}_{k , m , p , - 1}^{″} {e}^{j2π k {λ}_{0} y} \qquad ( EQ 16 )$$

Using the determined probability function of y the direct MLD module 234, at step 512, calculates the LLR for the b_{m,p} at the m-th antenna

$$L ( {\hat{b}}_{m , p} ) = log \frac{p ( y \vert {b}_{m , p} = + 1 )}{p ( y \vert {b}_{m , p} = - 1 )} \qquad ( EQ 18 )$$

The direct MLD module 234, at step 514, determines if all LLR information bits have been calculated. If the result of this determination is positive, the control flow exits at step 516. If the result of this determination is negative, the control flows returns to step 510 to calculate LLR for every bit of all transmitting antennas.

Non-Limiting Examples

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

What is claimed is:

1. A method, for performing Maximum Likelihood Detection, the method comprising:
accepting at least one data signal on at least one communication channel, wherein the data signal is modulated with a plurality of transmitted bit values;
sampling the at least one data signal in a characteristic function domain of the data signal to produce characteristic function samples;
determining, based upon the characteristic function samples, a probability density function associated with the at least one data signal; and
determining, based upon the probability density function, soft decision values for each transmitted bit value for each dimension of the at least one data signal.

2. The method of claim 1, wherein the characteristic function samples are determined as periodically sampled with a sampling period that is determined based at least on a signal-to-noise ratio associated with the wireless communication channel.

3. The method of claim 1, wherein the characteristic function samples in the characteristic function domain are determined by one of random sampling and pseudo-random sampling.

4. The method of claim 1, wherein the characteristic domain samples are determined based on at least a channel gain associated with the communication channel and an a priori estimated relative probability information associated with each channel bit value transmitted through the at least one communications channel.

5. The method of claim 1, wherein the determining characteristic domain samples determines characteristic domain samples in only one dimension.

6. The method of claim 1, further comprising:
determining a set of refined soft decision values by combining the soft decision values that have been determined over each dimension associated with the received signal for each corresponding bit in the plurality of transmitted bit values of each dimension.

7. The method of claim 1, wherein the probability density function is determined using a one-point Fourier transform.

8. The method of claim 1, wherein the determining the soft decision values further comprises:
determining a soft Log Likelihood Ratio value for each bit in the plurality of transmitted bit values using the probability density function.

9. A wireless device comprising:
a memory;
a processor communicatively coupled to the memory; and
a direct maximum likelihood detection module communicatively coupled to the memory and the processor, wherein the direct maximum likelihood detection module comprises:
a receiver adapted to accept at least one data signal on at least one communication channel, wherein the data signal is modulated with a plurality of transmitted bit values;
a characteristic domain sampler, communicatively coupled to the receiver, adapted to sample the at least one data signal in a characteristic function domain of the data signal to produce characteristic function samples;
a probability density function determiner, communicatively coupled to the characteristic domain sampler, adapted to determine, based upon the characteristic function samples, a probability density function associated with the at least one data signal; and
a soft decision value determiner, communicatively coupled to the probability density function determiner, adapted to determine, based upon the probability density function, soft decision values for each transmitted bit value for each dimension of the at least one data signal.

10. The wireless device of claim 9, wherein the characteristic domain sampler periodically samples the characteristic domain samples with a sampling period that is determined based at least on a signal-to-noise ratio associated with the wireless communication channel, and wherein the characteristic domain sampler determines characteristic domain samples based on at least a channel transfer function gain associated with the wireless communication channel and an a priori estimated relative probability information associated with each channel bit value transmitted through the at least one wireless communications channel.

11. The wireless device of claim 9, wherein the characteristic domain sampler is adapted to determine characteristic domain samples in only one dimension.

12. The wireless device of claim 9, wherein the soft decision value determiner is further adapted to determine a set of refined soft decision values combining the soft decision values that have been determined over each dimension associated with the received signal for each corresponding bit in the plurality of transmitted bit values of each dimension.

13. The wireless device of claim 9, wherein the probability density function determiner is adapted to determine the probability density function by using a one-point Fourier transform.

14. The wireless device of claim 9, wherein the soft decision value determiner is further adapted to:
determine a soft Log Likelihood Ratio value for each bit in the plurality of transmitted bit values using the probability density function.

15. A wireless communication system for performing Maximum Likelihood Detection, the wireless communication system comprising:
a plurality of base stations;
a plurality of wireless devices, wherein each wireless device in the plurality of wireless devices is communicatively coupled to at least one base station in the plurality of base stations;
wherein at least one of a base station and a wireless device comprises a
a direct maximum likelihood detection module, wherein the direct maximum likelihood detection module comprises:
a receiver adapted to accept at least one data signal on at least one communication channel, wherein the data signal is modulated with a plurality of transmitted bit values;
a characteristic domain sampler, communicatively coupled to the receiver, adapted to sample the at least one data signal in a characteristic function domain of the data signal to produce characteristic function samples;
a probability density function determiner, communicatively coupled to the characteristic domain sampler, adapted to determine, based upon the characteristic function samples, a probability density function associated with the at least one data signal; and
a soft decision value determiner, communicatively coupled to the probability density function determiner, adapted to determine, based upon the probability density function, soft decision values for each transmitted bit value for each dimension of the at least one data signal.

16. The wireless communication system of claim 15, wherein the characteristic domain sampler periodically samples the characteristic domain samples with a sampling period that is determined based at least on a signal-to-noise ratio associated with the wireless communication channel, and wherein the characteristic domain sampler determines characteristic domain samples based on at least a channel transfer function gain associated with the wireless communication channel and an a priori estimated relative probability information associated with each channel bit value transmitted through the at least one wireless communications channel.

17. The wireless communication system of claim 15, wherein the characteristic domain sampler is adapted to determine characteristic domain samples in only one dimension.

18. The wireless communication system of claim 15, wherein the soft decision value determiner is further adapted to determine a set of refined soft decision values combining the soft decision values that have been determined over each dimension associated with the received signal for each corresponding bit in the plurality of transmitted bit values of each dimension.

19. The wireless communication system of claim 15, wherein the probability density function determiner is adapted to determine the probability density function by using a one-point Fourier transform.

20. The wireless communication system of claim 15, wherein the soft decision value determiner is further adapted to:
determine a soft Log Likelihood Ratio value for each bit in the plurality of transmitted bit values using the probability density function.
